(19) United States
(12) Patent Application Publication
(10) Pub. No.: US 2024/0274715 A1
(43) Pub. Date: Aug. 15, 2024

(54) SEMICONDUCTOR DEVICE HAVING ANISOTROPIC LAYER

(71) Applicant: UNITED MICROELECTRONICS CORP., Hsin-Chu City (TW)

(72) Inventors: Kai-Hsiang Wang, Taichung City (TW); Yi-Fan Li, Tainan City (TW); Chung-Ting Huang, Kaohsiung City (TW); Chi-Hsuan Tang, Kaohsiung City (TW); Chun-Jen Chen, Tainan City (TW); Ti-Bin Chen, Tainan City (TW); Chih-Chiang Wu, Tainan City (TW)

(73) Assignee: UNITED MICROELECTRONICS CORP., Hsin-Chu City (TW)

(21) Appl. No.: 18/123,995

(22) Filed: Mar. 21, 2023

(30) Foreign Application Priority Data
Feb. 13, 2023 (CN) 202310107548.5

(51) Int. Cl. H01L 29/78; H01L 29/165; H01L 29/66

(52) U.S. Cl. CPC H01L 29/7848; H01L 29/165; H01L 29/66636

(57) ABSTRACT

A semiconductor device includes a gate structure on a substrate and an epitaxial layer adjacent to the gate structure, in which the epitaxial layer includes a first buffer layer, an anisotropic layer on the first buffer layer, a second buffer layer on the first buffer layer, and a bulk layer on the anisotropic layer. Preferably, a concentration of boron in the bulk layer is less than a concentration of boron in the anisotropic layer, a concentration of boron in the first buffer layer is less than a concentration of boron in the second buffer layer, and the concentration of boron in the second buffer layer is less than the concentration of boron in the anisotropic layer.

### BACKGROUND OF THE INVENTION

### 1. Field of the Invention

The invention relates to a semiconductor device, and more particularly, to a semiconductor device having an anisotropic layer in an epitaxial layer.

### 2. Description of the Prior Art

In order to increase the carrier mobility of semiconductor structure, it has been widely used to apply tensile stress or compressive stress to a gate channel. For instance, if a compressive stress were to be applied, it has been common in the conventional art to use selective epitaxial growth (SEG) technique to form epitaxial structure such as silicon germanium (SiGe) epitaxial layer in a silicon substrate. As the lattice constant of the SiGe epitaxial layer is greater than the lattice constant of the silicon substrate thereby producing stress to the channel region of PMOS transistor, the carrier mobility is increased in the channel region and speed of MOS transistor is improved accordingly. Conversely, silicon carbide (SiC) epitaxial layer could be formed in silicon substrate to produce tensile stress for gate channel of NMOS transistor.

However, epitaxial layers serving as primary stress-inducing structure in non-planar metal-oxide semiconductor (MOS) transistors, such as fin field effect transistors (FinFET) today are difficult to obtain an even surface through the fabrication process, thereby affecting the performance of the device. Hence, how to improve the current fabrication to resolve this issue has become an important task in this field.

### SUMMARY OF THE INVENTION

According to an embodiment of the present invention, a semiconductor device includes a gate structure on a substrate and an epitaxial layer adjacent to the gate structure, in which the epitaxial layer includes a first buffer layer, an anisotropic layer on the first buffer layer, a second buffer layer on the first buffer layer, and a bulk layer on the anisotropic layer. Preferably, a concentration of boron in the bulk layer is less than a concentration of boron in the anisotropic layer, a concentration of boron in the first buffer layer is less than a concentration of boron in the second buffer layer, and the concentration of boron in the second buffer layer is less than the concentration of boron in the anisotropic layer.

According to another aspect of the present invention, a semiconductor device includes a gate structure on a substrate and an epitaxial layer adjacent to the gate structure. Preferably, the epitaxial layer includes a first concentration of boron expanding along a first direction and a second concentration of boron expanding along a second direction, in which an angle included between the first direction and the second direction is between 35-65 degrees.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating semiconductor device according to an embodiment of the present invention.

### DETAILED DESCRIPTION

Referring to FIGS. 1-5, FIGS. 1-5 illustrate a method for fabricating semiconductor device according to an embodiment of the present invention. As shown in FIG. 1, a substrate 12 is provided and gate structures 14, 16 are formed on the substrate 12. In this embodiment, the formation of the gate structures 14, 16 could be accomplished by sequentially forming a gate dielectric layer, a gate material layer, and a hard mask on the substrate 12, conducting a pattern transfer process by using a patterned resist (not shown) as mask to remove part of the hard mask, part of the gate material layer, and part of the gate dielectric layer through single or multiple etching processes, and then stripping the patterned resist. This forms gate structures 14 and 16 each composed of a patterned gate dielectric layer 18, a patterned gate material layer 20, and a patterned hard mask 22.

It should be noted that even though two gate structures 14, 16 are disclosed in this embodiment, the quantity or number of the gate structures 14, 16 is not limited to two, but could all be adjusted according to the demand of the product. Moreover, only part of the gate structures 14, 16, such as the right portion of the gate structure 14 and left portion of the gate structure 16 are shown in the figures to emphasize the formation of buffer layer and epitaxial layer between gate structures 14, 16 in later process.

In this embodiment, the substrate 12 could be a semiconductor substrate such as a silicon substrate, an epitaxial substrate, a SiC substrate, or a silicon-on-insulator (SOI) substrate, but not limited thereto. The gate dielectric layer 18 could include SiO₂, SiN, or high-k dielectric material, the gate material layer 20 could include metal, polysilicon, or silicide, and the hard mask 22 could be selected from the group consisting of SiO₂, SiN, SiC, and SiON.

According to an embodiment of the present invention, a plurality of doped wells or shallow trench isolations (STIs) could be selectively formed in the substrate 12. Despite the present invention pertains to a planar MOS transistor, it would also be desirable to apply the process of the present invention to non-planar transistors such as FinFET devices, and in such instance, the substrate 12 shown in FIG. 1 would become a fin-shaped structure formed atop a substrate 12.

Next, at least one spacer 24 is formed on sidewalls of the gate structures 14 and 16.

Optionally, after a lightly doped ion implantation processes is conducted, a rapid thermal annealing processes is performed at about 930° C. to active the dopants implanted in the substrate 12 for forming lightly doped drains 26 in the substrate 12 adjacent to two sides of the spacer 24. In this embodiment, the spacer 24 could be a single or composite spacer, in which the spacer 24 could further include an offset spacer (not shown) and a main spacer (not shown). The offset spacer and the main spacer are preferably made of different material while the offset spacer and main spacer could all be selected from the group consisting of SiO₂, SiN, SiON, and SiCN, but not limited thereto.

Next, a dry etching and/or wet etching process is conducted by using the gate structures 14, 16 and spacers 24 as mask to remove part of the substrate 12 through single or multiple etching processes for forming recesses 28 in the substrate 12 adjacent to two sides of the gate structures 14, 16. Preferably, the etching process could be accomplished by first conducting a dry etching process to form initial recesses (not shown) in the substrate 12 adjacent to two sides of the gate structure 16, and then conducting a wet etching process to expand the recesses isotropically for forming recess 28. According to an embodiment of the present invention, the wet etching process could be accomplished using etchant including but not limited to for example ammonium hydroxide (NH₄OH) or tetramethylammonium hydroxide (TMAH). It should be noted that the formation of the recesses 28 is not limited to the combination of dry etching process and wet etching process addressed previously. Instead, the recesses 28 could also be formed by single or multiple dry etching and/or wet etching processes, which are all within the scope of the present invention. According to an embodiment of the present invention, each of the recess 28 could have various cross-section shapes, including but not limited to for example a circle, a hexagon, or an octagon. Despite the cross-section of the recess 28 in this embodiment pertains to be a hexagon, it would also be desirable to form the recess 28 with aforementioned shapes, which are all within the scope of the present invention.

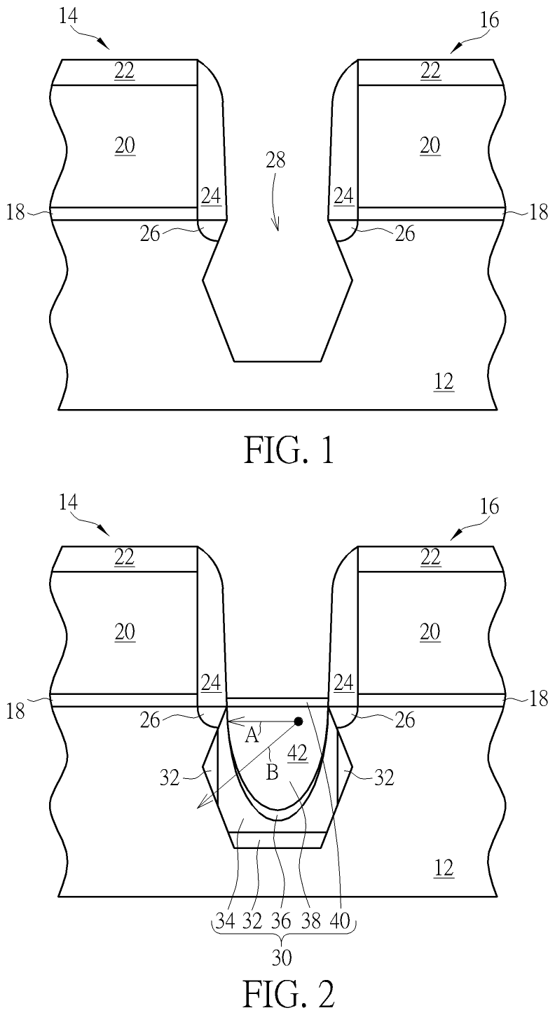

Next, as shown in FIG. 2, a selective epitaxial growth (SEG) is conducted by using gas such as dichlorosilane (DCS) to form an epitaxial layer 30 in each of the recesses 28, in which the epitaxial layer 30 includes a first buffer layer 32 disposed on a surface of the recess 28, a second buffer layer 34 disposed on the first buffer layer 32, an anisotropic layer 36 disposed on the second buffer layer 34, a bulk layer 38 disposed on the anisotropic layer 36, and a cap layer 40 disposed on the bulk layer 38.

In this embodiment, a top surface of the epitaxial layer 30 such as the top surface of the first buffer layer 32, the top surface of the second buffer layer 34, the top surface of the anisotropic layer 36, and the top surface of the bulk layer 38 are preferably even with a top surface of the substrate 12, in which the epitaxial layer 30 also shares substantially same cross-section shape with the recess 28. For instance, the cross-section of the epitaxial layer 30 could also include a circle, a hexagon, or an octagon depending on the demand of the product. In this embodiment, the epitaxial layer 30 could also be formed to include different material depending on the type of transistor being fabricated. For instance, if the MOS transistor being fabricated were to be a PMOS transistor, the epitaxial layer 30 could be made of material including but not limited to for example SiGe, SiGeB, or SiGeSn. If the MOS transistor being fabricated were to be a NMOS transistor, the epitaxial layer 30 could be made of material including but not limited to for example SiC, SiCP, or SiP.

Moreover, the SEG process could also be adjusted to form a single-layered epitaxial structure or multi-layered epitaxial structure, in which heteroatom such as germanium atom or carbon atom of the structure could be formed to have gradient while the surface of the epitaxial layer 30 is preferred to have less or no germanium atom at all to facilitate the formation of silicide afterwards. It should be noted that even though the top surfaces of the substrate 12 and epitaxial layer 30 are coplanar in this embodiment, it would also be desirable extend the epitaxial layer 30 upward so that the top surface of the epitaxial layer 30 or the top surfaces of the first buffer layer 32, the second buffer layer 34, the anisotropic layer 36, and the bulk layer 38 are higher than the top surface of the substrate 12 according to another embodiment of the present invention.

Next, an ion implantation process is conducted to form a source/drain region 42 in part or all of the epitaxial layer 30. According to another embodiment of the present invention, the source/drain region 42 could also be formed insituly during the SEG process. For instance, the source/drain region 42 could be formed by implanting p-type dopants during formation of a SiGe epitaxial layer, a SiGeB epitaxial layer, or a SiGeSn epitaxial layer for PMOS transistor, or could be formed by implanting n-type dopants during formation of a SiC epitaxial layer, SiCP epitaxial layer, or SiP epitaxial layer for NMOS transistor. By doing so, it would be desirable to eliminate the need for conducting an extra ion implantation process for forming the source/drain region. Moreover, the dopants within the source/drain region 42 could also be formed with a gradient, which is also within the scope of the present invention.

It should be noted the epitaxial layer 30 in this embodiment preferably includes SiGe and the first buffer layer 32, the second buffer layer 34, the anisotropic layer 36, and the bulk layer 38 preferably include different concentration of boron. For instance, the concentration of boron in the bulk layer 38 is preferably less than the concentration of boron in the anisotropic layer 36, the concentration of boron in the first buffer layer 32 is less than the concentration of boron in the second buffer layer 34, and the concentration of boron in the second buffer layer 34 is less than the concentration of boron in the anisotropic layer 36, in which the concentration of boron in the first buffer layer 32 is close to or equal to zero.

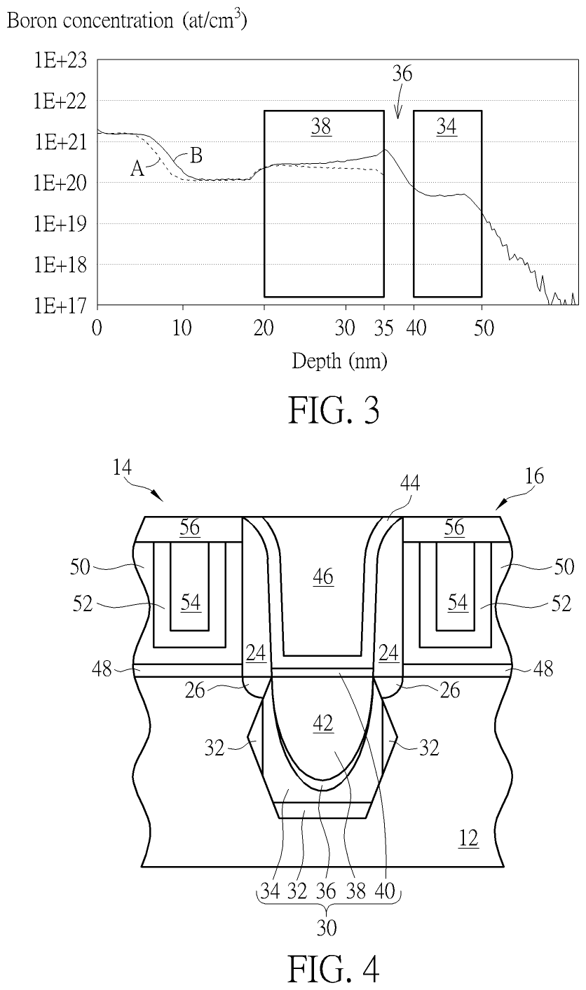

Referring to FIGS. 2-3, FIG. 3 illustrates a distribution diagram between boron concentration and corresponding depth thereof along the arrow A direction and arrow B direction in the epitaxial layer 30, in which the Y-axis in FIG. 3 represents boron concentration, X-axis represents corresponding depth, dotted line A represents boron concentration and corresponding depth along the arrow A direction, and line B represents boron concentration and corresponding depth along the arrow B direction. Preferably, the arrow A is extending along and in parallel with the surface of the substrate 12 while arrow B is extending toward the bottom of the substrate 12, in which the angle included between arrow A and arrow B is preferably between 35 to 65 degrees or most preferably at 45 degrees.

It should be noted that the depth shown in FIG. 3 not only refers to the distance measured from the top surface of the epitaxial layer 30 downward along the Y-direction as shown in FIG. 2, but also refers to the distance measured from the intersecting point of the two arrows A and B shown in FIG. 2 toward left along the direction of each of the arrows A and B. For instance, the depths corresponding to dotted line A (or arrow A) shown in the X-axis of FIG. 3 refers to the distance measured from the intersecting point of the two arrows A and B toward left as shown in FIG. 2 and the depths corresponding to line B (or arrow B) as shown in FIG. 3 refers to the distance measured from the intersecting point of the two arrows A and B toward bottom left direction as shown in FIG. 2.

As shown in FIG. 3, the concentration distribution lines A and B preferably have relatively same concentration from depth 0 to depth 35 nm in the bulk layer 38. In other words, the concentration of boron measured from the intersecting point of the two arrows A and B in FIG. 3 toward left along the direction of arrow A until reaching the borderline or edge of the bulk layer 38 is substantially equal to the concentration of boron measured from the intersecting point of the two arrows A and B toward lower left direction of arrow B until reaching the edge of the bulk layer 38. Preferably, this depth is the end of the distribution line A and the arrow A.

It should be noted that between depths 30-40 nm or more specifically before entering 35 nm, the boron concentration of distribution line A is slightly lower than the boron concentration of distribution line B. In other words, before reaching depth of 35 nm or borderline of the bulk layer 38, the boron concentration of arrow A is slightly less than the boron concentration of arrow B. Nevertheless, after surpassing the depth of 35 nm, the distribution line B or arrow B then enters the region of the anisotropic layer 36 and the extension of the distribution line A or the arrow A now stops here. Since the boron concentrations of the bulk layer 38 and the second buffer layer 34 are both less than the boron concentration of the anisotropic layer 36, the distribution line B going beyond the depth of 35 nm would increase to first reach a small peak and then gradually decrease and then enter the region of the second buffer layer 34 after passing depth of 40 nm.

It should also be noted that even though the boron concentration of the anisotropic layer 36 may seem to be greater than the boron concentration at the boundary between the bulk layer 38 and the anisotropic layer 36, the fact that the bulk layer 38 includes a gradient concentration of boron such that the boron concentration closer to the top surface of the bulk layer 38 is slightly greater than the boron concentration at the boundary of the bulk layer 38, the boron concentration of the anisotropic layer 36 could then be substantially equal to the boron concentration closer to the top surface of the bulk layer 38 or boron concentration of the bulk layer 38 between 0-10 nm.

As the depth surpasses 40 nm, the concentration of the distribution line B or arrow B continues to decrease such that the boron concentration of the distribution line B between depth 40-50 nm is preferably lower than the boron concentration of the distribution line B between depth 35-40 nm. Similarly if the depth continues to increase beyond 50 nm or enters the first buffer layer 32 zone, the concentration of the distribution line B or arrow B would continue to decrease so that the boron concentration of the distribution line B between depth 50-60 nm is lower than the boron concentration of the distribution line B between depth 40-50 nm.

Next, as shown in FIG. 4, a contact etch stop layer (CESL) 44 could be formed on the substrate 12 surface to cover the gate structures 14, 16 and the cap layer 40, and an interlayer dielectric (ILD) layer 46 is formed on the CESL 44 afterwards. Next, a planarizing process such as a chemical mechanical polishing (CMP) process is conducted to remove part of the ILD layer 46 and part of the CESL 44 so that the top surfaces of the hard mask 22 and ILD layer 46 are coplanar.

Next, a replacement metal gate (RMG) process is conducted to transform the gate structures 14, 16 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the hard masks 22, the gate material layer 20, and even the gate dielectric layer 18 from gate structures 14, 16 for forming recesses (not shown) in the ILD layer 46. Next, a selective interfacial layer 48 or gate dielectric layer (not shown), a high-k dielectric layer 50, a work function metal layer 52, and a low resistance metal layer 54 are formed in the recesses, and a planarizing process such as CMP is conducted to remove part of low resistance metal layer 54, part of work function metal layer 52, and part of high-k dielectric layer 50 to form metal gates. In this embodiment, each of the gate structures or metal gates fabricated through high-k last process of a gate last process preferably includes an interfacial layer 48 or gate dielectric layer (not shown), a U-shaped high-k dielectric layer 50, a U-shaped work function metal layer 52, and a low resistance metal layer 54.

In this embodiment, the high-k dielectric layer 50 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 52 is formed for tuning the work function of the metal gate in accordance with the conductivity of the device. For an NMOS transistor, the work function metal layer 52 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 52 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 52 and the low resistance metal layer 54, in which the material of the barrier layer may include titanium (Ti), titanium nitride (TiN), tantalum (Ta) or tantalum nitride (TaN). Furthermore, the material of the low-resistance metal layer 54 may include copper (Cu), aluminum (Al), titanium aluminum (TiAl), cobalt tungsten phosphide (CoWP) or any combination thereof.

Next, part of the high-k dielectric layer 50, part of the work function metal layer 52, and part of the low resistance metal layer 54 are removed to form recesses (not shown), and hard masks 56 are then formed into the recesses so that the top surfaces of the hard masks 56 and ILD layer 46 are coplanar. The hard masks 56 could be made of material including but not limited to for example SiO₂, SiN, SiON, SiCN, or combination thereof.

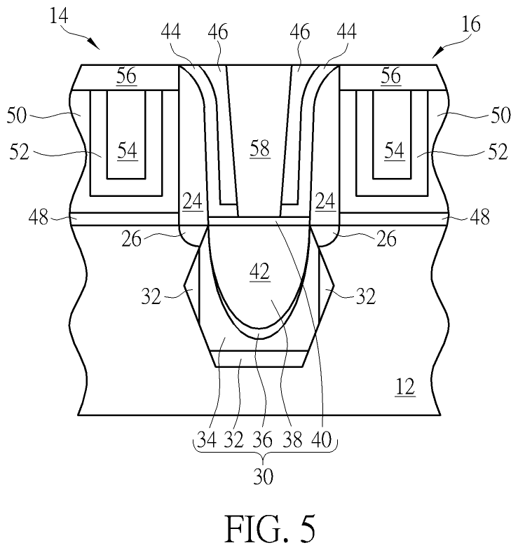

Next, as shown in FIG. 5, a photo-etching process is conducted by using a patterned mask (not shown) as mask to remove part of the ILD layer 46 and part of the CESL 44 adjacent to the gate structures 14, 16 for forming contact holes (not shown) exposing the cap layer 40 underneath. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 58 electrically connecting the source/drain regions 42. This completes the fabrication of a semiconductor device according to an embodiment of the present invention.

Overall, the present invention preferably forms an anisotropic layer 36 between the second buffer layer 34 and the bulk layer 38 during formation of the epitaxial layer, in which the anisotropic layer 36 does not grow along the arrow A as shown in FIG. 2 but instead grow along the arrow B direction to form a substantially crescent moon profile. According to a preferred embodiment of the present invention, the thickness of the anisotropic layer 36 extend along the arrow A direction is between 5-50 Angstroms while the maximum thickness of the anisotropic layer 36 at the bottom is between 10-100 Angstroms. Preferably, the boron concentration of the anisotropic layer 36 is slightly greater than the boron concentration of the bulk layer 38 and the second buffer layer 34.

Nevertheless, according to other embodiment of the present invention, the boron concentration of the anisotropic layer 36 could also be less than the boron concentration of the bulk layer 38 but greater than the boron concentration of the second buffer layer 34 and in this instance, the boron concentration of the anisotropic layer 36 is approximately 10% to 60% of the boron concentration of the bulk layer 38. By controlling the boron concentration of the anisotropic layer 36 to be slightly less than that of the bulk layer 38, it would be desirable to reduce diffusion of boron atoms toward arrow B direction but facilitate diffusion of boron atoms toward arrow A direction thereby improving reliability and stability of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a gate structure on a substrate; and
an epitaxial layer adjacent to the gate structure, wherein the epitaxial layer comprises:
a first buffer layer;
an anisotropic layer on the first buffer layer; and
a bulk layer on the anisotropic layer, wherein a concentration of boron in the bulk layer is less than a concentration of boron in the anisotropic layer.

2. The semiconductor device of claim 1, further comprising a second buffer layer between the first buffer layer and the anisotropic layer.

3. The semiconductor device of claim 2, wherein a concentration of boron in the first buffer layer is less than a concentration of boron in the second buffer layer.

4. The semiconductor device of claim 2, wherein a concentration of boron in the second buffer layer is less than the concentration of boron in the anisotropic layer.

5. The semiconductor device of claim 1, further comprising a cap layer on the bulk layer.

6. A semiconductor device, comprising:
a gate structure on a substrate; and
an epitaxial layer adjacent to the gate structure, wherein the epitaxial layer comprises:
a first concentration of boron expanding along a first direction; and
a second concentration of boron expanding along a second direction, wherein an angle included between the first direction and the second direction is between 35-65 degrees.

7. The semiconductor device of claim 6, wherein the first direction is parallel to a surface of the substrate.

8. The semiconductor device of claim 6, wherein the second direction is toward a bottom of the substrate.

9. The semiconductor device of claim 6, wherein the first concentration of boron expanding at a first depth is less than the second concentration of the boron expanding at the first depth.

10. The semiconductor device of claim 9, wherein the first depth is between 30-40 nm.

11. The semiconductor device of claim 6, wherein the second concentration of boron expanding at a first depth is less than the second concentration of boron expanding at a second depth.

12. The semiconductor device of claim 11, wherein the second depth is between 40-50 nm.

13. The semiconductor device of claim 6, wherein the second concentration of boron expanding at a third depth is less than the second concentration of boron expanding at a second depth.

14. The semiconductor device of claim 13, wherein the third depth is between 50-60 nm.
